(19) United States
(12) Patent Application Publication
(10) Pub. No.: US 2023/0088400 A1
(43) Pub. Date: Mar. 23, 2023

(54) CONTROL MODULE AND CONTROL METHOD THEREOF FOR SYNCHRONOUS DYNAMIC RANDOM ACCESS MEMORY

(71) Applicant: REALTEK SEMICONDUCTOR CORPORATION, HSINCHU (TW)

(72) Inventors: CHEN-TUNG LIN, HSINCHU (TW); YA-MIN CHANG, HSINCHU (TW)

(21) Appl. No.: 17/932,507

(22) Filed: Sep. 15, 2022

(30) Foreign Application Priority Data
Sep. 17, 2021 (TW) 110134900

(51) Int. Cl. G06F 3/06

(52) U.S. Cl. CPC G06F 3/0613; G06F 3/0673; G06F 3/0629; G06F 3/0659

(57) ABSTRACT

The present disclosure provides a control module and a control method thereof for an SDRAM. The control module includes a register and a controller. The controller is configured to: select a first command, wherein the first command includes at least two first memory commands; execute one of the at least two first memory commands; store an un-executed memory command of the at least two first memory commands in a register and back the un-executed memory command up as at least one first back-up memory command; select a second command, wherein the first command and the second command are stored in different memory bank groups; and execute the second command.

### CROSS REFERENCE TO RELATED APPLICATIONS

This application claims priority of Taiwan application No. 110134900 filed on Sep. 17, 2021, which is incorporated by reference in its entirety.

### BACKGROUND

### Field of the Invention

The present invention relates generally to a technique of a control module and a control method thereof for a memory, in particular, to a control module and a control method thereof for a synchronous dynamic random access memory.

### Description of Related Art

In synchronous dynamic random access memory (SDRAM) architecture, the access efficiency of the memory can be improved through the setup of multiple memory bank groups and the round-robin access mechanism in which data is accessed in different memory bank groups. However, when a general command is split into a plurality of single memory commands with data associations and stored in a plurality of memory banks of the same memory bank group, using the round-robin access mechanism to accessing data in the memory bank group will cause the single memory commands with data associations to be processed separately, which will in turn result in a decrease in the command processing performance.

### BRIEF SUMMARY OF THE INVENTION

Some embodiments of the present invention provide a control method of a synchronous dynamic random access memory (SDRAM). The control method includes: selecting a first command, wherein the first command includes at least two first memory commands; executing one of the at least two first memory commands; backing up an un-executed memory command of the at least two first memory commands in a register and as at least one first back-up memory command; selecting a second command, wherein the first command and the second command are stored in different memory bank groups; and executing the second command.

Some embodiments of the present invention provide a control module for use in an SDRAM. The control module includes a register and a controller. The controller is configured to: select a first command, wherein the first command includes at least two first memory commands; execute one of the at least two first memory commands; store an un-executed memory command of the at least two first memory commands in a register and back the un-executed memory command up as at least one first back-up memory command; select a second command, wherein the first command and the second command are stored in different memory bank groups; and execute the second command.

### BRIEF DESCRIPTION OF THE DRAWINGS

Aspects of the present invention are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram illustrating a control module according to some embodiments of the present disclosure.

FIG. 2 is a block diagram illustrating a control module 2 according to some embodiments of the present disclosure.

FIG. 3 is a flowchart of a control method for controlling the SDRAM according to some embodiments of the present disclosure.

FIGS. 4A and 4B are flowcharts of a control method for controlling the SDRAM according to some embodiments of the present disclosure.

### DETAILED DESCRIPTION

Embodiments of the present invention are discussed in detail below. It should be appreciated, however, that the present invention provides many applicable inventive concepts that can be embodied in a wide variety of specific contexts. The specific embodiments discussed are merely illustrative and do not limit the scope of the disclosure.

In conventional synchronous dynamic random access memory (SDRAM) architecture, when a general command is split into a plurality of single memory commands with data associations and stored in a plurality of memory banks of the same memory bank group, using the round-robin access mechanism to accessing data in the memory bank group will cause the single memory commands with data associations to be processed separately, which will in turn result in a decrease in the command processing performance. The present disclosure provides a control module and a control method thereof in order to increase the performance of the operation of the SDRAM architecture.

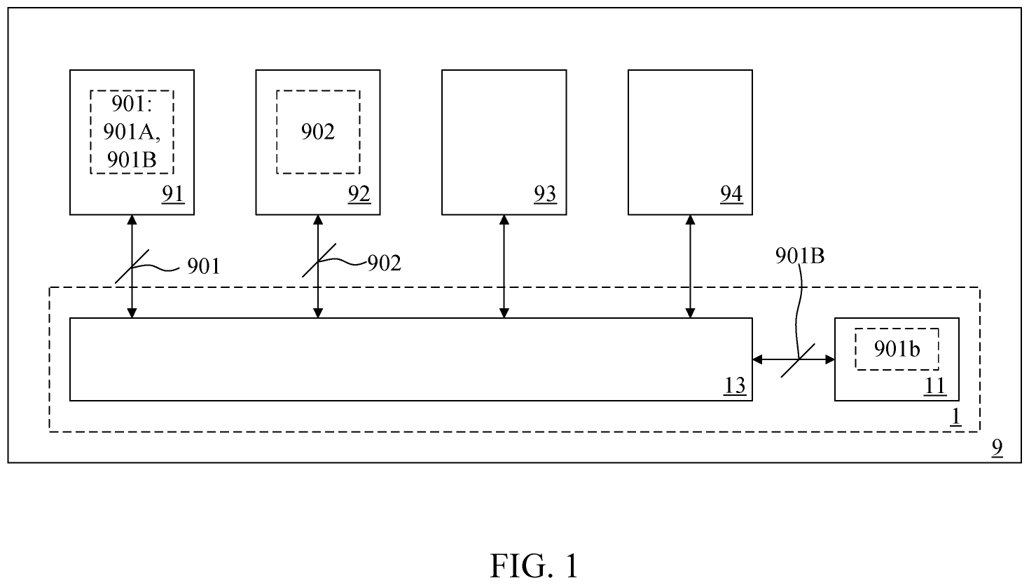

Reference is made to FIG. 1, which a block diagram illustrating a control module 1 according to some embodiments of the present disclosure. The control module 1 includes a register 11 and a controller 13. The register 11 and the controller 13 are electrically connected. The control module 1 is configured to be used for a synchronous dynamic random access memory (SDRAM) 9. The SDRAM 9 has a plurality of memory bank groups 91 to 94. Data and signals are transmitted between the components via electric connections. The related control operations are discussed further below.

In some embodiments, the memory bank group 91 has a first command 901 stored therein, and the memory bank group 92 has a second command 902 stored therein. The controller 13 selects the first command 901 from the memory bank group 91. The first command 901 includes at least two first memory commands 901A and 901B. The controller 13 executes the first memory command 901A. Subsequently, the controller 13 stores the first memory command 901B that is un-executed to the register 11 and backs up the first memory command 901B as a first backup memory command 901b. Next, the controller 13 selects the second command 902 from the memory bank group 92 and executes the second command 902.

In some embodiments, after the controller 13 completes executing the second command 902, the controller 13 executes the first backup memory command 901b (i.e., the first memory command 901B), that is un-executed, in the register 11. Accordingly, the execution interval between the first memory commands 901A and 901B that have high data association relevance is only the operation time of one memory bank group (e.g., the memory bank action command waiting time tRRD_S, the memory bank read/write command waiting time tCCD_S, the memory bank write command waiting time tWTR_S, etc.), so as to avoid the low overall access efficiency caused by the operation delay caused by the round-robin mechanism of all memory bank groups 91 to 94.

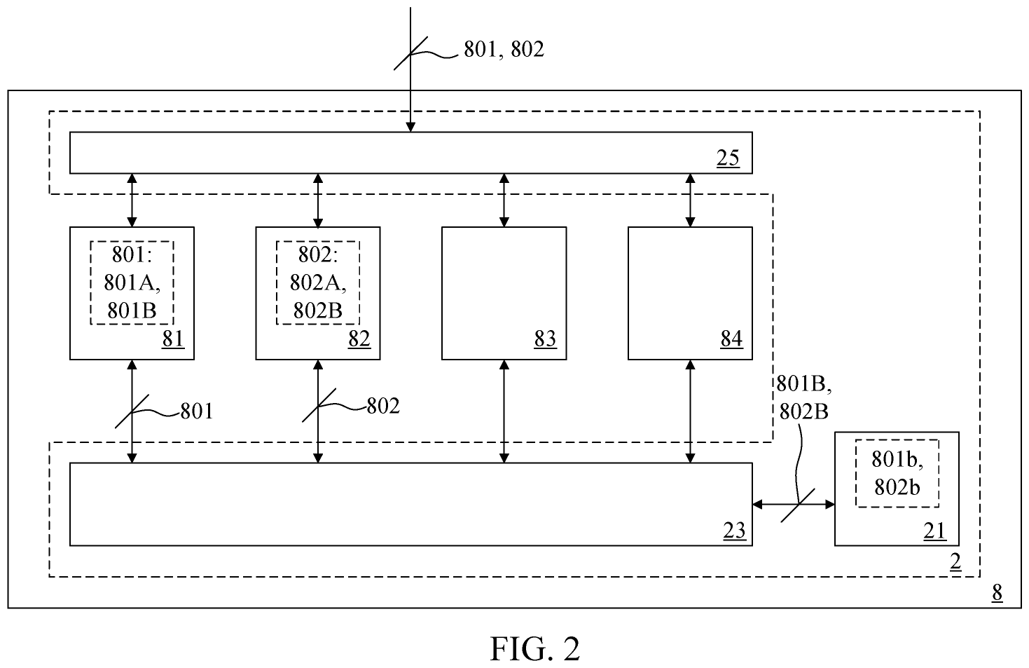

Reference is made to FIG. 2, which is a block diagram illustrating a control module 2 according to some embodiments of the present disclosure. The control module 2 includes a register 21, a controller 23, and a memory grouper 25. The register 21 and the controller 23 are electrically connected. The control module 2 is configured to be used for an SDRAM 8. The SDRAM 8 has a plurality of the memory bank groups 81 to 84. The memory grouper 25 is configured to group the command from a bus (not shown) to different memory bank groups. Data and signals are transmitted between the components via electric connections. The related control operations are discussed further below.

In some embodiments, memory grouper 25 stores a first command 801 to the memory bank group 81, and stores a second command 802 to the memory bank group 82. The controller 23 selects the first command 801 from the memory bank group 81. The first command 801 includes at least two first memory commands 801A and 801B. The controller 23 executes the first memory command 801A. Subsequently, the controller 23 stores the first memory command 801B that is un-executed to the register 21 and backs up the first memory command 801B as a first backup memory command 801b.

Next, the controller 23 selects the second command 802 from the memory bank group 82. The second command 802 includes at least two second memory commands 802A and 802B. The controller 23 executes the second memory command 802A. Subsequently, the controller 23 stores the second memory command 802B that is un-executed to the register 21 and backs up the second memory command 802B as a second backup memory command 802b.

After the controller 23 completes executing the second memory command 802A, the controller 23 first determines whether the register 21 has therein a memory command associated with the memory bank group 81 that is un-executed. If yes, said un-executed memory command is executed. Otherwise, the command from the next memory bank group (e.g., memory bank group 83) is selected and executed. In these embodiments, the controller 23 determines that the register 21 has stored therein the first backup memory command 801b that is un-executed. Therefore, the controller 23 may execute the first backup memory command 801b (i.e., the first memory command 801B).

After the controller 23 completes executing the first backup memory command 801b (i.e., the first memory command 801B), the controller 23 first determines whether the register 21 has therein a memory command associated with the memory bank group 82 that is un-executed. If yes, said un-executed memory command. Otherwise, the command from the next memory bank group (e.g., memory bank group 83) is selected and executed. In these embodiments, the controller 23 determines that the register 21 has stored therein the second backup memory command 802b that is un-executed. Therefore, the controller 23 may execute the second backup memory command 802b (i.e., the second memory command 802B).

Accordingly, by executing the first command 801 (including the first memory command 801A and 801B) of the memory bank group 81 and the second command 802 of the memory bank group 82 (including the second memory command 802A and 802B) alternatingly, the execution interval between the first memory commands 801A and 801B that have high data association relevance is only the operation time of one memory bank group (e.g., the tRRD_S, tCCD_S, tWTR_S, etc.), and the execution interval between the first memory commands 802A and 802B that have high data association relevance is only the operation time of one memory bank group ((e.g., the tRRD_S, tCCD_S, tWTR_S, etc.), so as to avoid the low overall access efficiency caused by the operation delay caused by the round-robin mechanism of all memory bank groups 81 to 84.

In particular, the backup memory commands of the preceding embodiments may contain a memory bank information, an address column information, an address row information, a command number, a remaining command length related to memory, or any combination of the memory bank information, the address column information, the address row information, the command number, the remaining command length. In this way, the controller can read and execute the corresponding back-up memory commands in the registers.

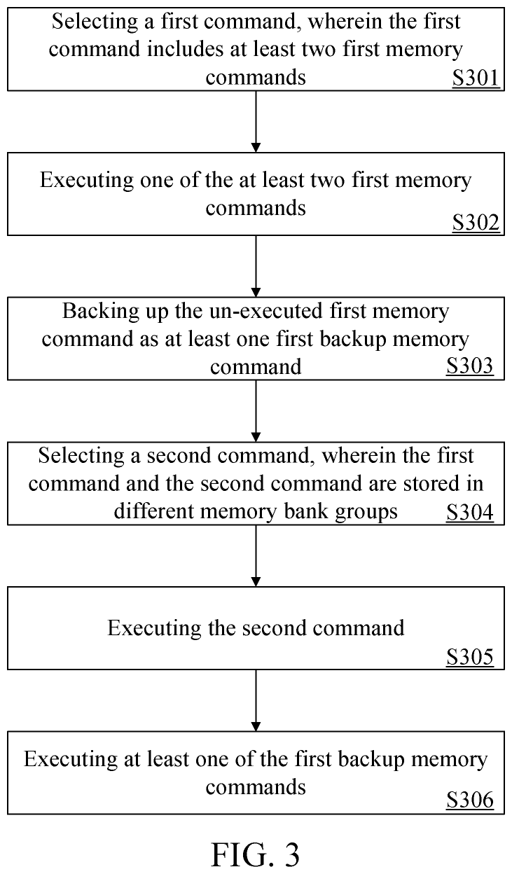

Some embodiments of the present disclosure include a control method for controlling the SDRAM. A flowchart thereof is shown in FIG. 3. The control method according to these embodiments can be implemented using a control module (such as the control module discussed in the foregoing embodiments), and a detailed operation of the method is as follows. First, in Step S301, a first command is selected, wherein the first command includes at least two first memory commands. Then in Step S302, one of the at least two first memory commands is executed. Next, in Step S303, the memory command of the at least two first memory command that is un-executed is backed up as at least one first backup memory command. Then in Step S304, a second command is selected, wherein the first command and the second command are stored in different memory bank groups. Next, in Step S305, the second command is executed. In some embodiments, after executing the second command, Step S306 is optionally executed, to execute at least one of the first backup memory commands.

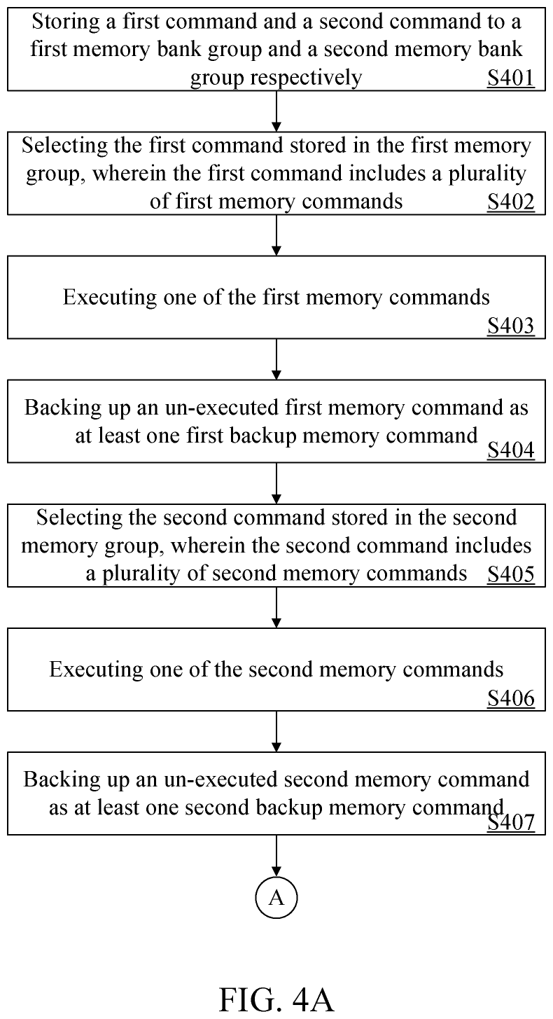

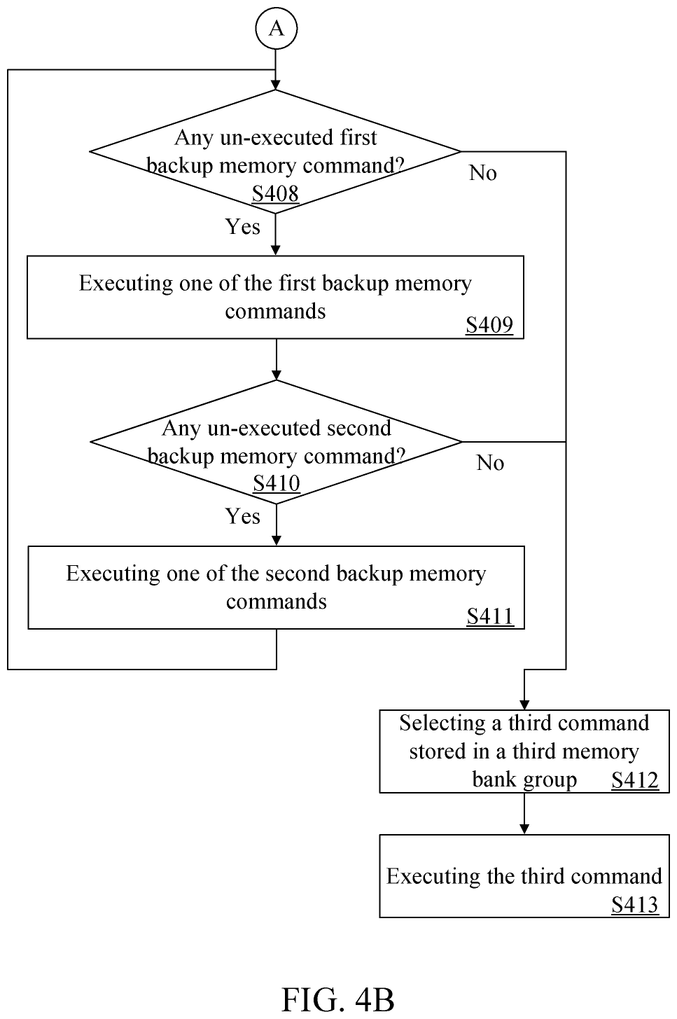

Some embodiments of the present disclosure include a control method for controlling the SDRAM. Flowcharts thereof are shown in FIGS. 4A and 4B. The control method according to these embodiments can be implemented using a control module (such as the control module discussed in the foregoing embodiments), wherein the SDRAM has at least two memory bank groups, and a detailed operation of the method is as follows.

First, in Step S401, a first command and a second command are respectively stored to a first memory bank group and a second memory bank group of the SDRAM. Then, in Step 402, the first command stored in first memory bank group is selected, wherein the first command includes a plurality of first memory commands. Then in Step S403, at least one of the plurality of first memory commands is executed. Next, in Step S404, the memory command of the plurality of first memory commands that is un-executed is backed up as at least one first backup memory command.

Then in Step S405, a second command stored in second memory bank group is selected, wherein the second command including a plurality of second memory commands. Next, in Step S406, one of the plurality of the second commands is executed. Then in Step S407, the memory command of the plurality of second memory commands that is un-executed is backed up as at least one second backup memory command.

Then in Step S408, it is determined whether at least one first backup memory command that is un-executed exists. If yes, in Step S409, one of the at least one first backup memory command is executed. Then in Step S410, it is determined whether at least one second backup memory command that is un-executed exists. If yes, in Step S411, one of the at least one second backup memory commands is executed.

In some embodiments, if the determination result in Step S408 is negative, then in Step S412, a third command stored in a third memory bank group is selected. Then in Step S413, the third command is executed. In these embodiments, since the determination result in Step S408 is negative, it means that the first command stored in first memory bank group has been executed completely; therefore, after the Step S413 completes, the control method according to the present disclosure can alternatingly confirm whether the memory command of the second command and the memory command of the third command have all been executed based on the preceding principles. When one of the commands has been executed completely, then a fourth command of a fourth memory bank group is selected and executed, and the foregoing command executing mode is repeated.

In some embodiments, if the determination result in Step S410 is negative, then in Step S412, a third command stored in third memory bank group is selected. Next in Step S413, the third command is executed. In these embodiments, since the determination result in Step S410 is negative, it means that the second command stored in second memory bank group has been executed completely; therefore, after the Step S413 finishes, the control method according to the present disclosure can alternatingly confirm whether the memory command of the first command and the memory command of the third command have all been executed based on the preceding principles and alternatingly execute the memory command that has not been executed completely. When one of the commands has been executed completely, then a fourth command of a fourth memory bank group is selected and executed, and the foregoing command executing mode is repeated.

In summary, a control module for use in SDRAM and a control method thereof provided by the present disclosure, are directed mainly to two commands of two memory bank groups, wherein the contents of one command is executed at a time, and if one of the commands has an unexecuted memory command after execution, the unexecuted memory command is backed up and the other command is executed next, and when the execution process of the other command is completed (e.g., the execution is completed or the memory command is backed up), then the backup commands are executed in the order of the backup commands are generated. In this way, two commands of two memory bank groups are executed in an alternating manner. When the execution of the commands of one of the memory bank groups is completed, the commands of the next memory bank group is read and the associated commands are executed in the same manner. It should be noted that in some embodiments, the controller includes logic circuits that can execute computations and commands, but they are not intended to limit the implementation of the hardware components of the present disclosure.

While this invention has been described with specific embodiments thereof, it is evident that many alternatives, modifications, and variations may be apparent to those skilled in the art. For example, various components of the embodiments may be interchanged, added, or substituted in the other embodiments. Also, all of the elements of each figure are not necessary for operation of the disclosed embodiments. For example, one of ordinary skill in the art of the disclosed embodiments would be enabled to make and use the teachings of the invention by simply employing the elements of the independent claims. Accordingly, embodiments of the invention as set forth herein are intended to be illustrative, not limiting. Various changes may be made without departing from the spirit and scope of the invention.

What is claimed is:

1. A control method of a synchronous dynamic random access memory (SDRAM), comprising:
selecting a first command, wherein the first command comprises at least two first memory commands;
executing one of the at least two first memory commands;
backing up an un-executed memory command of the at least two first memory commands as at least one first backup memory command;
selecting a second command, wherein the first command and the second command are stored in different memory bank groups; and
executing the second command.

2. The control method of claim 1, further comprising:
after executing the second command, executing one of the at least one first backup memory command.

3. The control method of claim 2, further comprising:
determining that the at least one first backup memory command that has not been executed exists.

4. The control method of claim 2, wherein the second command comprises at least two second memory commands, and the step of executing the second command further comprises:
executing one of the at least two second memory commands.

5. The control method of claim 4, further comprising:
backing up an un-executed memory command of the at least two second memory commands as at least one second backup memory command.

6. The control method of claim 5, further comprising:
after executing one of the at least one first backup memory command, executing one of the at least one second backup memory command.

7. The control method of claim 6, further comprising:
determining that the at least one second backup memory command that has not been executed exists.

8. The control method of claim 1, further comprising:
storing the first command and the second command to a first memory bank group and a second memory bank group of the SDRAM respectively.

9. The control method of claim 8, wherein the SDRAM has at least two memory bank groups.

10. The control method of claim 1, wherein the at least one first backup memory command comprises a memory bank information, an address column information, an address row information, a command number, a remaining command length, or any combination of the memory bank information, the address column information, the address row information, the command number, the remaining command length.

11. A control module for use in a synchronous dynamic random access memory (SDRAM), comprising:
a register; and
a controller, electrically connected to the register and configured to:
select a first command, wherein the first command comprises at least two first memory commands;
execute one of the at least two first memory commands;
store an un-executed memory command of the at least two first memory command to the register and back the un-executed memory command up as the at least one first backup memory command;
select a second command, wherein the first command and the second commands are stored in different memory bank groups; and
execute the second command.

12. The control module of claim 11, wherein the controller is further configured to:
after executing the second command, execute one of the at least one first backup memory command in the register.

13. The control module of claim 12, wherein the controller is further configured to:
determine that the register has therein the at least one first backup memory command that has not been executed.

14. The control module of claim 12, wherein the second command comprises at least two second memory commands, and the controller is further configured to:
execute one of the at least two second memory commands.

15. The control module of claim 14, wherein the controller is further configured to:
store an un-executed memory command of the at least two second memory commands to the register and back the un-executed memory command up as at least one second backup memory command.

16. The control module of claim 15, wherein the controller is further configured to:
after executing one of the at least one first backup memory command, execute one of the at least one second backup memory command in the register.

17. The control module of claim 16, wherein the controller is further configured to:
determine that the register has therein the at least one second backup memory command that has not been executed.

18. The control module of claim 11, further comprising:
a memory grouper, configured to store the first command and the second command to a first memory bank group and a second memory bank group of the SDRAM respectively.

19. The control module of claim 18, wherein the SDRAM has at least two memory bank groups.

20. The control module of claim 11, wherein the at least one first backup memory command comprises a memory bank information, an address column information, an address row information, a command number, a remaining command length, or any combination of the memory bank information, the address column information, the address row information, the command number, the remaining command length.
